(19) United States
(12) Patent Application Publication
(10) Pub. No.: US 2008/0171142 A1
(43) Pub. Date: Jul. 17, 2008

(54) Film Deposition Method And Film Deposition System

(76) Inventors: Kenji Matsumoto, Yamanashi-ken (JP); Tomoyuki Sakoda, Yamanashi-ken (JP); Masayuki Nasu, Yamanashi-ken (JP); Gaku Ikeda, Yamanashi-ken (JP)

Correspondence Address: SMITH, GAMBRELL & RUSSELL, 1130 CONNECTICUT AVENUE, N.W., SUITE 1130, WASHINGTON, DC, 20036, US

(21) Appl. No.: 11/883,075

(22) PCT Filed: Jan. 11, 2006
(86) PCT No.: PCT/JP2006/300206

§ 371 Date: Jul. 26, 2007

(30) Foreign Application Priority Data
Feb. 10, 2005 (JP) 2005-035298

(51) Int. Cl. B05D 5/12; C23C 16/02

(52) U.S. Cl. 427/126.3; 118/708

(57) ABSTRACT

There is provided a film deposition method of depositing a multielement metal oxide film capable of depositing a multielement metal oxide film having a desired composition and a desired thickness in an improved repeatability. A film deposition method deposits a multielement metal oxide film on a surface of a workpiece by a film depositing process including supplying organometallic source gases generated by atomizing a plurality of organometallic compounds into a processing vessel capable of being evacuated. A dummy film deposition process corresponding to at least three cycles of the film deposition process is carried out by placing a dummy workpiece in the processing vessel and supplying the organometallic source gases into the processing vessel immediately before starting the film deposition process for depositing a multielement metal oxide film on the workpiece. Thus a multielement metal oxide film having a desired composition and a desired thickness can be deposited in an improved repeatability.

### TECHNICAL FIELD

The present invention relates to a film deposition method and a film deposition system for depositing a thin film of a multielement metal oxide on a semiconductor wafer or the like.

### BACKGROUND ART

Generally, a ferrorelectric storage device is widely noticed as a nonvolatile storage device of the next generation for IC cards. Active research & development activities have been made on ferroelectric storage devices. The ferroelectric storage device is a semiconductor device employing a ferroelectric capacitor formed by holding a ferroelectric film between two electrodes as a memory cell. A ferroelectric material has a property that exhibits a spontaneous polarization hysteresis which maintains charges generated therein by applying a voltage thereto after the voltage has been removed. The ferroelectric storage device is a nonvolatile storage device using such a property of the ferroelectric material.

A multielement metal oxide film containing oxides of a plurality of metals is a known ferroelectric film for forming the capacitor of such a ferroelectric storage device. A film of Pb (ZrₓTi₁₋ₓ)O₃ (hereinafter, referred to as “PZT film) is an example of widely used multielement metal oxide films.

For example, the PZT film is a Pb(ZrₓTi₁₋ₓ)O₃ Perovskite crystalline film deposited by a CVD system (chemical vapor deposition system) by using organometallic compounds and an oxidizer. The organometallic compounds are, for example, Pb(DPM)₂, namely, Pb(C₁₁H₁₉O₂)₂ (lead bis-dipivaloylmethanate) (hereinafter referred to as “Pb-base material”), Zr(OiPr)(DPM)₃, namely, Zr(O-i-C₃H₇)(C₁₁H₁₉O₂)₃ (zirconium(i-propoxy)tris(dipivaloymethanate) (hereinafter, referred to as “Zr-base maternal”) and Ti(OiPr)₂(DPM)₂, namely, Ti(O-i-C₃H₇)₂(C₁₁H₁₉O₂)₂ (titanium di(i-propoxy)bis-(dipivaloylmethanate) (hereinafter referred to as “Ti-base material”). The oxidizer is, for example, NO₂. Such a PZT film is disclosed in Patent document 1. In the foregoing description Pb, Zr and Ti indicate lead, zirconium and titanium, respectively.

Source gases of the foregoing materials and an oxidation gas are supplied individually through a shower head into a processing vessel to deposit the PZT film by a CVD method. Those source gases and the oxidation gas are diffused in separate diffusing chambers in the shower head, respectively, are spouted through separate gas jetting pores into the processing vessel, respectively, and are mixed in the processing vessel to produce a mixed gas. The mixed gas comes into contact with a semiconductor wafer placed in the processing vessel. The semiconductor wafer is heated at a temperature suitable for the growth of a PZT film. The source gases and the oxidation gas interact to form the PZT film on the semiconductor wafer. The foregoing method of mixing the source gases and the oxidation gas in the processing vessel is called a postmixing method.

Patent document 1:JP 2002-9062 A

### DISCLOSURE OF THE INVENTION

### Problem to be Solved by the Invention

On the forgoing film system, when the film deposition process is resumed after the completion of maintenance work, such as cleaning inside surfaces and repair, for the film deposition system, after a long idling operation or after changing the temperature of the processing vessel or the like, there is differences of an atomic-level between the condition of the inside surfaces of the processing vessel and the atmosphere in the processing vessel immediately after the completion of a film deposition process and that of the same at the resumption of the film deposition process. Consequently, in some cases, the repeatability of the film deposition process in depositing a new PZT film is deteriorated by changes in the condition of the inside surfaces and the atmosphere in the processing vessel. Since a wafer carried into the processing vessel is heated and the source gases are not supplied into the processing vessel at an initial stage of the film deposition process, gases of the atmosphere in the processing vessel come into contact with the wafer, adhere to the wafer, reactions and changes the surface condition of the wafer before the process gases reach the wafer. It is considered that the degree of change of the surface condition is greatly dependent on the concentration of the gases of the atmosphere.

Therefore, a dummy film deposition process for processing a dummy wafer is carried out before resuming the film deposition process for depositing a PZT film on a wafer after the maintenance or after a long idling to suppress the deterioration of the repeatability of the film deposition process for depositing a PZT film. The dummy film deposition process is intended to adjust the condition of the inside surfaces of the processing vessel and the atmosphere in the processing vessel to those immediately after the completion of the film deposition process and to stabilize the film deposition process.

However, since the dummy film deposition process is carried out only once, there are some cases where the composition of a PZT film formed on a wafer changes and the Pb content of the PZT film, in particular, changes from wafer to wafer, and the repeatability of the PZT film deposition process is unsatisfactory.

The present invention has been made in view of the foregoing problems to solve those problems effectively. Accordingly, it is an object of the present invention to provide a film deposition method and a film deposition system capable of depositing multielement metal oxide films having a desired composition and a desired thickness in an improved repeatability.

### Means for Solving the Problem

A film deposition method in a first aspect of the present invention deposits a multielement metal oxide film on a surface of a workpiece by a film depositing process including supplying organometallic source gases generated by atomizing a plurality of organometallic compounds into a processing vessel capable of being evacuated; wherein a dummy film deposition process corresponding to at least three cycles of the film deposition process is carried out by placing a dummy workpiece in the processing vessel and supplying the organometallic source gases into the processing vessel immediately before starting the film deposition process for depositing a multielement metal oxide film on a workpiece. Since the dummy film deposition process is repeated at least three times by placing a dummy workpiece in the processing vessel and supplying the organometallic source gases into the processing vessel immediately before starting the film deposition process for depositing a multielement metal oxide film on a workpiece, the film deposition method is capable of depositing a multielement metal oxide film having a desired composition and a desired thickness in an improved repeatability.

The plurality of organometallic compounds includes a Pb-base organometallic compound.

A film deposition system for depositing a multielement metal oxide film on a surface of a workpiece in a second aspect of the present invention includes: a processing vessel capable of being evacuated; a stage for supporting a workpiece thereon; a heating means for heating the workpiece supported on the stage; and a gas supply means for supplying a plurality of organometallic gases into the processing vessel; wherein the partial pressure of a gas containing a predetermined metal and contained in an atmosphere in the processing vessel or in an exhaust gas discharged from the processing vessel is measured by a partial pressure measuring device, and a control unit carries out control operations, immediately before starting a film deposition process for processing a workpiece, to carry out a dummy film deposition process including supplying the organometallic gases into the processing vessel holding a dummy workpiece, repeating the dummy film deposition process until the partial pressure of the gas containing the predetermined metal measured by the partial pressure measuring device immediately after the completion of the dummy film deposition process is not lower than a predetermined pressure level, and starting the film deposition process for processing the workpiece after the measured partial pressure has exceeded the predetermined pressure level.

Preferably, the plurality of organometallic compounds include a Pb-base organometallic compound.

Preferably, the predetermined pressure level is 3.0×10⁻⁴ Pa.

### Effect of the Invention

The film deposition method and the film deposition system according to the present invention have the following excellent operations and effects.

Since the dummy film deposition process is repeated at least three times by placing a dummy workpiece in the processing vessel and supplying the organometallic source gases into the processing vessel immediately before starting the film deposition process for depositing a multielement metal oxide film on a workpiece, the film deposition method and the film deposition system are capable of depositing a multielement metal oxide film having a desired composition and a desired thickness in an improved repeatability.

### BRIEF DESCRIPTION OF THE DRAWINGS

FIG. 1 is a diagrammatic view of a film deposition system according to the present invention;

FIG. 2 is a flow chart of a film deposition method in a first embodiment according to the present invention;

FIG. 3 is a graph showing the variation of the concentrations of elements in the atmosphere in a processing vessel with time after the completion of the film deposition process;

FIG. 4 is a graph showing the variation of the concentrations of elements in the atmosphere in the processing vessel with the number of cycles of a dummy film deposition process;

FIG. 5 is a graph showing the relation between the repeatability of the thickness and the contents of elements in a PZT film and the number of cycles of a dummy film deposition process;

FIG. 6 is a table of partial pressures of the elements of the atmosphere in the processing vessel immediately after the completion of the dummy film deposition process for the numbers of dummy wafers processed by the dummy film deposition process;

FIG. 7 is a flow chart of a film deposition method in a second embodiment according to the present invention;

FIG. 8 is a flow chart of a first known film deposition process;

FIG. 9 is a flow chart of a second known film deposition process; and

FIG. 10 is a flow chart of an improved film deposition process.

### BEST MODE FOR CARRYING OUT THE INVENTION

A film deposition method and a film deposition system embodying the present invention will be described with reference to the accompanying drawings.

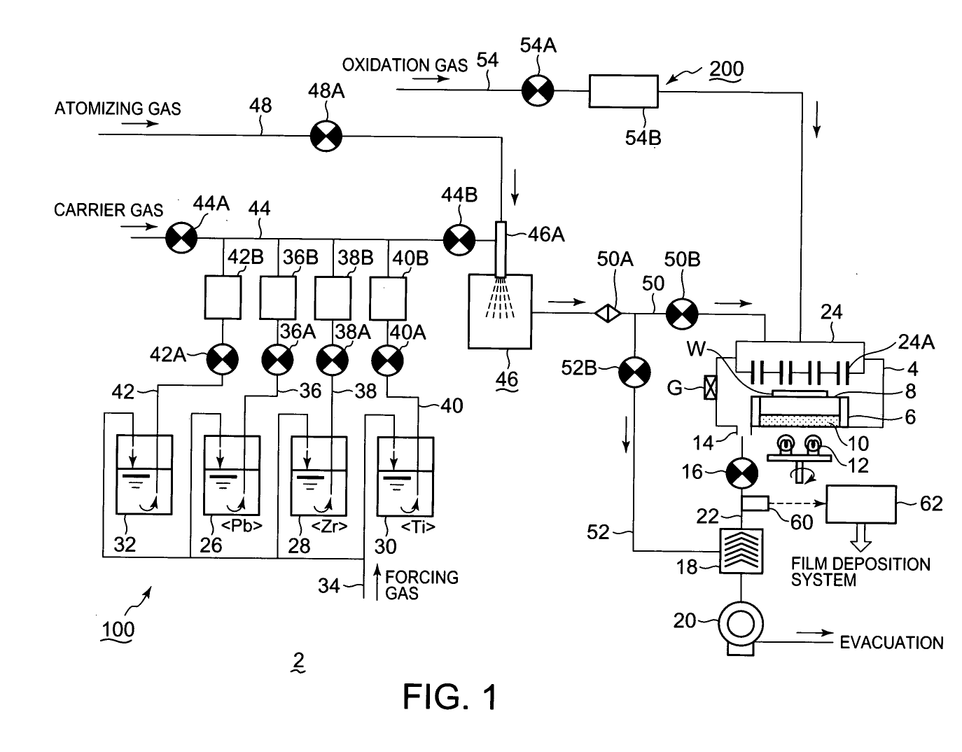

Referring to FIG. 1 showing a film deposition system 2 according to the present invention, the film deposition system 2 has a cylindrical processing vessel 4 made of, for example, aluminum. A cylindrical support member 6 is set on the bottom wall of the processing vessel 4. A plate-shaped stage 8 made of, for example AIN is supported on an upper end part of the support member 6. A semiconductor wafer W, namely, a workpiece, or a dummy wafer, namely, a dummy workpiece, is held on the stage 8.

A transparent plate 10 of quartz or the like is tightly fitted in an opening formed in the bottom wall of the processing vessel 4. A rotary member supporting a plurality of heating lamps 12, namely, heating means, is disposed below the transparent plate 10. Heat rays emitted by the heating lamps 12 can penetrate the transparent plate 10 and can heat the stage 8 and a wafer W supported on the stage 8. A gate valve G is attached to the side wall of the processing vessel 4. The gate valve G is opened when a wafer W is carried into and the wafer is carried out of the processing vessel 4. Lifting pins, not shown are disposed under the stage 8 to receive a wafer W carried into the processing vessel 4 and to lift up a wafer W from the stage 8 to carry the wafer W away from the processing vessel 4.

An exhaust port 14 is formed in a peripheral part of the bottom wall of the processing vessel 4. An exhaust line 22 provided with a shut-off valve 16, an exhaust trap 18 and connected to a vacuum pump 20 is connected to the exhaust port 14 to evacuate the processing vessel 4 by the vacuum pump 20. A pressure regulating valve, not shown, such as a butterfly valve, is placed in the exhaust line 22 to regulate the pressure in the processing vessel 4.

A shower head 24 is incorporated into the top wall of the processing vessel 4 opposed to the stage 8. Organic metal source gasses are supplied through the shower head 24 into the processing vessel 4. The source gases are spouted through gas spouting pores 24A formed in a gas spouting surface of the shower head 24.

A source gas supply system 100 and an oxidation gas supply system 200 are connected to a shower head 24. More specifically, the source gas supply system 100 has three source material tanks 26, 28 and 30 respectively containing liquid organometallic compounds, namely, a Pb-base material, a Zr-base material and a Ti-base material, and a solvent tank 32 containing a solvent for dissolving the liquid organometallic compounds, such as butyl acetate. A forcing gas supply line 34 is connected to the tanks 26, 28, 30 and 32 respectively to supply a forcing gas, such as He, Ar or N₂, into spaces extending over the liquids contained in the tanks 26, 28, 30 and 32. Liquid supply lines 36, 38, 40 and 42 are extended respectively into the liquids contained in the tanks 26, 28, 30 and 32. The forcing gas forces the liquids into the liquid supply lines 36, 38, 40 and 42. Shutoff valves 36A, 28A, 40A and 42A, and flow controllers 36B, 38B, 40B and 42B, such as mass flow controllers, are placed in the liquid supply lines 36, 38, 40 and 42, respectively.

The liquid supply lines 36, 38, 40 and 42 are connected to a carrier gas supply line 44 for carrying a carrier gas, such as He, Ar or N₂. The carrier gas supply line 44 is connected to a spray nozzle 46A included in an atomizer 46. Shutoff valves 44A and 44B are placed in a part on the upstream side and a part on the downstream side of the carrier gas supply line 44. An atomizing gas supply line 48 is connected to the spray nozzle 46A to supply an atomizing gas, such as He, Ar or N₂, to the spray nozzle 46A. The liquid materials forced together with the carrier gas into the spray nozzle 46A are atomized by the atomizing gas to produce source gases, a shutoff valve 48A is placed in the atomizing gas supply line 48.

A source gas supply line 50 has one end connected to the exit of the atomizer 46 and the other end connected to the shower head 24. A filter 50A and a first selector valve 50B are placed in that order with respect to a fluid flowing direction in the source gas supply line 50. A bypass line 52 has one end connected to a part between the filter 50A and the first selector valve 50B of the source gas supply line 50 and the other end connected to the exhaust trap 18. A second selector valve 52B is placed in the bypass line 52. The source gases are supplied continuously, and the first selector valve 50B and the second selector valve 52B are controlled to supply the source gases selectively into the processing vessel 4 or the bypass line 52.

An oxidation gas supply line 54 is connected to the shower head 24 to supply an oxidation gas into the shower head 24. A shutoff valve 54A and a flow controller 54B, such as a mass flow controller, are placed in that order with respect to the flowing direction of the oxidation gas in the oxidation gas supply line 54. The oxidation gas may be O₂, O₃, N₂O or NO₂. As mentioned above, the source gases and the oxidation gas are supplied separately into the shower head 24 through separate gas jetting pores, not shown, respectively. Thus the gases are mixed in a postmixing mode.

When necessary, the film deposition system 2 is provided with a partial pressure measuring device 60 to measure the partial pressure of a predetermined metal-containing gas contained in the atmosphere in the processing vessel 4 or the exhaust gas discharged from the processing vessel 4. In this embodiment, the partial pressure measuring device 60 is placed in a part of the exhaust line 22 on the upstream side of the exhaust trap 18. The partial pressure measuring device 60 may be placed on the side wall of the processing vessel 4.

The partial pressure measuring device 60 may be a FT-IR (Fourier transform infrared spectrometer) or a Q-mass spectrometer (quadrupole mass spectrometer). If necessary, the film deposition system 2 may be provided with a gas cell and a differential exhaust system. Such film deposition systems are disclosed in JP 4-362176 A, JP 2001-68465 A and JP 2001-284336 A. Those known film deposition systems supply source gases into a processing vessel holding a wafer W therein and measure the concentrations of the source gases in the atmosphere in the processing vessel. Measured data is fed back to a source gas supply system for the stable control of supplying the source gases. According to the present invention, the partial pressure measuring device 60 measures the partial pressures of the source gases and the concentrations of the source gases in an atmosphere containing the source gases (metal-containing gases) in the processing vessel 4 in a state where any wafer W is not held in the processing vessel 4 and the source gases are not supplied into the processing vessel 4. The present invention decides whether the next cycle of the film deposition process is to be started to process the next wafer or a dummy film deposition process is to be started to process a dummy wafer by a dummy film deposition process on the basis of the measured data. The measured data is not fed back to the source gas supply system.

The measured data provided by the partial pressure measuring device 60 is given to a control unit 62 including a microcomputer for controlling the operations of the film deposition system. The control unit 62 carries out a dummy film deposition process immediately before starting the film deposition process for processing a wafer W. In the dummy film deposition process, a dummy wafer is placed in the processing vessel 4 and the source gases are supplied into the processing vessel 4. The dummy film deposition process is repeated until a measured value provided by the partial pressure measuring device 60 exceeds a predetermined value. The control unit 62 starts the film deposition process for processing a wafer W after the measured value provided by the partial pressure measuring device 60 has exceed the predetermined value. The partial pressure of the metal-containing gas, for example the Pb-base gas, is measured. The predetermined value for the partial pressure of the Pb-base gas is, for example, 3.0×10⁻⁴ Pa. The control unit 62 controls the operations of the film deposition system even if the film deposition system is not provided with the partial pressure measuring device 60.

A film deposition method to be carried out by the film deposition system will be described.

First the flow of the source gases will be described. The vacuum pump 20 is driven to evacuate the film deposition system. The inside spaces of the tanks 26, 28, 30 and 32 are pressurized by the forcing gas supplied through the forcing gas supply line 34 into the tanks 26, 28, 30 and 32. The shutoff valves 36A, 38A, 40A and 42A placed in the liquid supply lines 36, 38, 40 and 42 are operated to supply the Pb-base material, the Zr-base material, the Ti-base material and the solvent into the shower head 24 as the occasion demands. The shutoff valves 36A, 38A and 40A are opened to supply the liquid materials. The respective flows of the liquid materials are controlled. The liquid materials are mixed into the carrier gas in the carrier gas supply line 44 and a mixture containing the liquid materials and the carrier gas flows to the spray nozzle 46A of the atomizer 46.

The liquid materials are atomized by the atomizer 46 into source gases by the agency of an atomizing gas supplied through the atomizing gas supply line 48 to the spray nozzle 46A. The source gases produced by the atomizer 46 flow through the source gas supply line 50. The source gases can be supplied into the processing vessel 4 or can be made to flow through the bypass line 52 into the exhaust line 22 by properly controlling the first selector valve 50B placed in the source gas supply line 50 and the second selector valve 52B placed in the bypass line 52. For example, it takes a certain time to stabilize the respective flow rates of the source gases after starting the supply of the source gases. Therefore, the source gases are made to flow through bypass line 52 and the exhaust line 22 instead of making the same to flow into the processing vessel 4 until the respective flow rates of the source gases stabilize. The oxidation gas is supplied through the oxidation gas supply line 54 of the oxidation gas supply system 200 simultaneously with the supply of the source gases into the processing vessel 4.

The source gases and the oxidation gas supplied into the shower head 24 placed on the top wall of the processing vessel 4 are spouted through separate spouting pores 24A into and mixed in the processing vessel 4. A wafer W or the like is held beforehand on the stage 8 and is heated at a predetermined temperature by heat generated by the heating lamps 12. The interior of the processing vessel is maintained at a predetermined process pressure. The source gases and the oxidation gas spouted through the spouting pores 24A of the shower head 24 into the processing vessel 4 interact and a PZT film is deposited on a surface of the wafer W or the like. the atmosphere in the processing vessel 4 is exhausted through the exhaust line 22. The trap 18 removes the source gases remaining in the exhausted atmosphere.

### First Embodiment

A film deposition method in a first embodiment according to the present invention will be described. The first embodiment does not use the partial pressure measuring device 60.

After all the wafers to be processed by the film deposition process have been processed, the film deposition system 2 is kept in an idling mode until the next lot of wafers are delivered to the film deposition system 2. In the idling mode, the processing vessel 4 is continuously evacuated, while the supply of the gases is stopped.

It is preferable to keep a dummy wafer on the stage 8 to protect the stage 8 if the stage 8 is kept at the process temperature while the film deposition system 2 is kept in the idling mode. The difference between the temperature of a surface of the shower head 24 facing a wafer (a surface facing the vacuum space) during the film deposition process and the temperature of the same in the idling mode is several tens degrees centigrade if any wafer is not placed on the stage. In such a case, deposits deposited on the surface of the shower head are caused to crack and fall by a thermal stress induced in the deposits. A wafer placed on the stage suppresses the variation of the temperature of the surface of the shower head and covers the stage. Power supplied to the heating lamps may be controlled so that the surface of the shower head is maintained at a temperature equal to that of the surface of the shower head during the film deposition process to prevent the separation of the deposits from the surface of the shower head due to the thermal stress induced therein.

If the film deposition process for depositing a film on a wafer is started directly following the idling mode, the condition of the inside surfaces of the processing vessel 4 and the atmosphere in the processing vessel 4 are unstable at the initial stage of the film deposition process. Therefore, the repeatability of the film deposition process for depositing a PZT film on several wafers at an initial stage of the film depositing operation deteriorates significantly. Stabilization of the inside surface of the processing vessel 4 and the atmosphere in the processing vessel 4 means the stabilization of the partial pressures of the source gases remaining in the processing vessel 4 at substantially fixed levels, respectively, or a state where the adhesion of molecules of the source gases to the inside surfaces of the processing vessel 4 and the desorption of molecules of the source gases from the inside surfaces of the processing vessel 4 equilibrate substantially with each other.

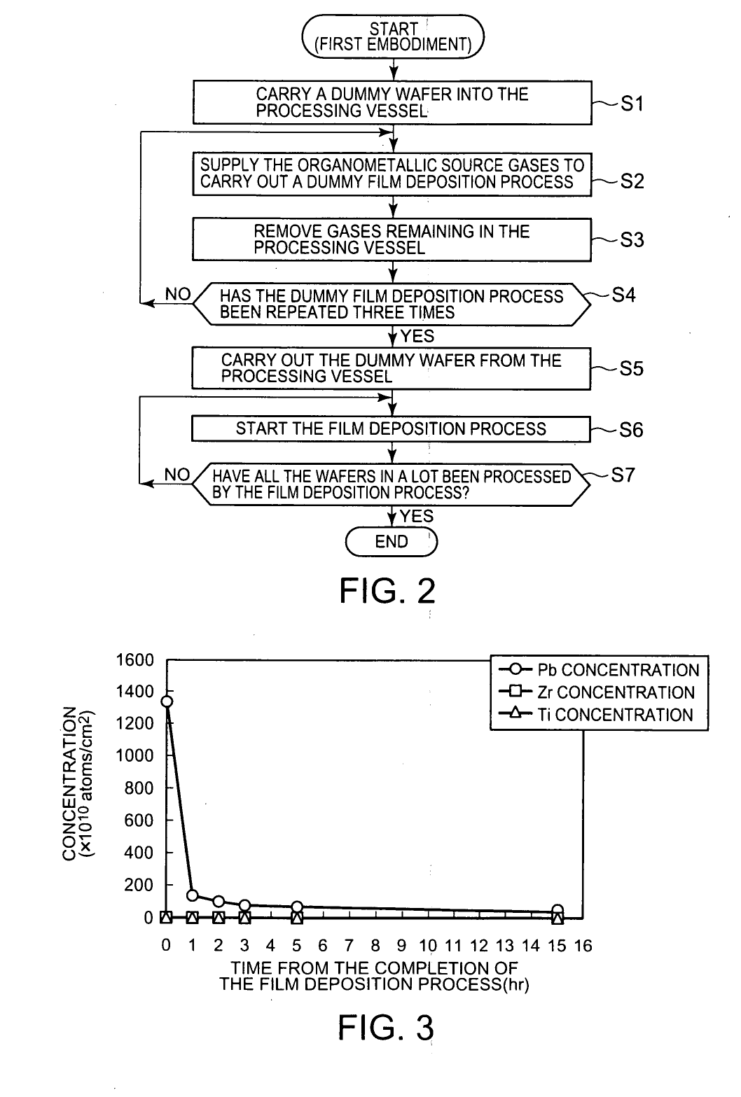

The first embodiment carries out a dummy film deposition process for processing a dummy wafer at least three times to stabilize the condition of the inside surfaces of the processing vessel 4 and the atmosphere in the processing vessel 4. FIG. 2 is a flow chart of the film deposition method in the first embodiment.

When a dummy film deposition process is started after the duration of the idling mode, a dummy wafer is carried into the processing vessel 4 and is placed on the stage 8 in step S1. Conditions for the dummy film deposition are the same as those for the film deposition process for depositing a film on a wafer W. The dummy film deposition process is carried out in step S2 by supplying the Pb-base, the Zr-base and the Ti-base source gas, namely, organometallic gases, and the oxidation gas into the processing vessel 4 and heating the dummy wafer. The dummy film deposition process is continued for a predetermined time.

After the dummy film deposition process has been continued for the predetermined time, the supply of the source gases and the oxidation gas is stopped and the gases remaining in the processing vessel 4 are removed in step S3 to complete the first cycle of the dummy film deposition process.

Steps S2 and S3 are repeated until a decision that the dummy film deposition process has been repeated three times is made in step S4. Thus the dummy film deposition process is carried out three times. A dummy wafer may be processed by three cycles of the dummy film deposition process or three dummy wafers may be processed by three cycles of the dummy film deposition process, respectively.

Only one cycle of the dummy film deposition process may be continued for a time three times the time for which the film deposition process is continued by supplying the source gases and the oxidation gas at flow rates equal to those at which the source gases and the oxidation gas are supplied in the film deposition process. It is also possible that only one cycle of the dummy film deposition process may be continued for a time equal to the time for which the film deposition process is continued by supplying the source gases and the oxidation gas at flow rates three times those at which the source gases and the oxidation gas are supplied in the film deposition process. Thus the dummy film deposition process is complete when the respective amounts of the source gases and the oxidation gas supplied in the dummy film deposition process are three times those of the source gases and the oxidation gas supplied in three cycles of the film deposition process.

The response to a query made in step S4 is affirmative when the dummy film deposition process equivalent to three cycles of the film deposition process has been completed. Then, the dummy wafer is carried out from the processing vessel 4 in step S5. Subsequently, a wafer W is carried into the processing vessel 4 and is subjected to the film deposition process in step S6. The film deposition process is performed continuously for, for example, a lot of twenty-five wafers W while the response to a query made in step S7 is negative. The response to a query made in step S7 is affirmative after all the wafers W in a lot have been processed and the film deposition process is ended and the film deposition system is kept in the idling mode.

The condition of the inside surfaces of the processing vessel 4 and the atmosphere in the processing vessel 4 can be stabilized by repeating the dummy film deposition process at least three times before starting the film deposition process after the film deposition system has been kept in the idling mode. Consequently, the repeatability of the composition and the thickness of the PZT film deposited on the surface of the wafer W can be improved. The concentration of Pb among the concentrations of the elements of the source gas remaining in the processing vessel 4 has a significant influence on the electric characteristic of the semiconductor device. The repeatability of the Pb concentration can be greatly improved.

Change of the concentrations of the elements in the exhaust gas, the relation between the number of cycles of the dummy film deposition process and the measured amount of each element, and the repeatability of film deposition were examined. Results of the examination will be described.

FIG. 3 is a graph showing the variation of the concentrations of the elements in the atmosphere in the processing vessel with time after the completion of the film deposition process. Time elapsed after twelve dummy wafers have been continuously processed is measured on the horizontal axis in FIG. 3. As obvious from the graph shown in FIG. 3, Zr and Ti are contained scarcely in the atmosphere from the beginning of a period subsequent to the completion of the film deposition process, and the Zr concentration and the Ti concentration of the atmosphere are stable. The concentration of Pb having a significant influence on the electric characteristic of the semiconductor device in the atmosphere changes sharply in a period of 1 hr subsequent to the completion of the film deposition process. It is known from FIG. 3 that the stabilization of the Pb concentration, in particular, should be taken into consideration in determining the number of cycles of the dummy film deposition cycle to be carried out for the stabilization of the atmosphere in the processing vessel.

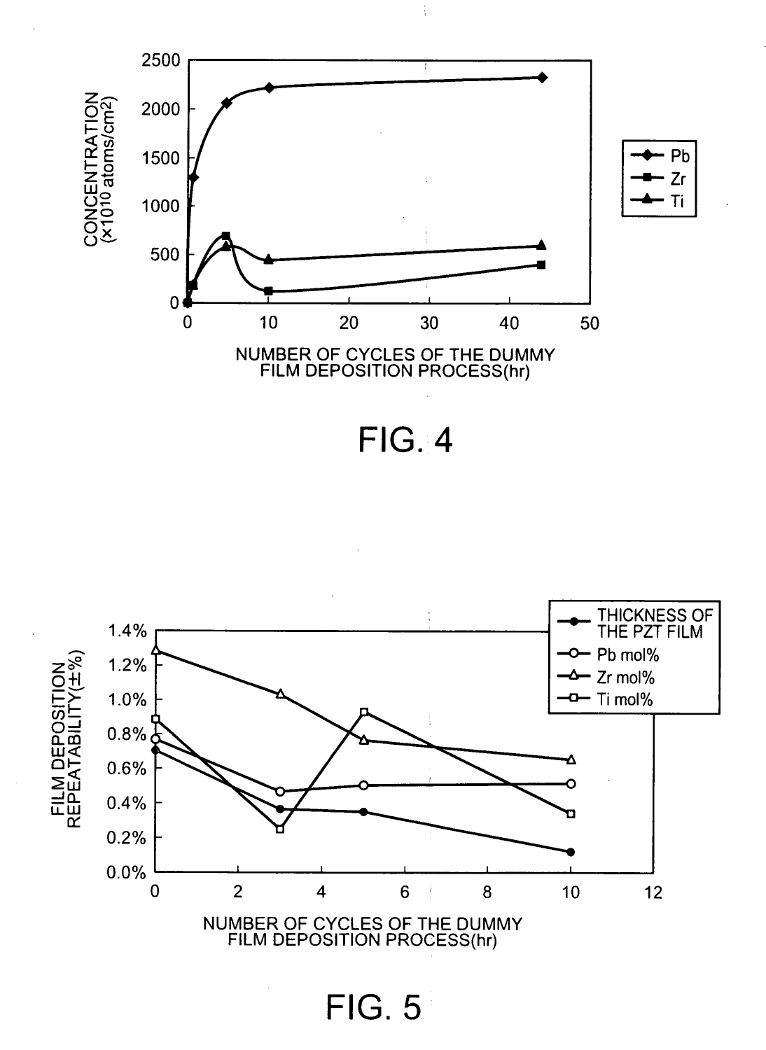

FIG. 4 is a graph showing the variation of the concentrations of the elements in the atmosphere in the processing vessel immediately after the completion of the dummy film deposition process with the number of cycles of the dummy film deposition process. As obvious from the graph shown in FIG. 4, the respective amounts of Zr and Ti do not change greatly after the first cycle of the dummy film deposition process, while the amount of Pb changes greatly after the first, the second and the third cycle of the dummy film deposition process and changes scarcely after the fourth cycle and the following cycles of the dummy film deposition process. Thus it was proved that the Pb concentration in the atmosphere in the processing vessel can be stabilized by at least three cycles of the dummy film deposition process.

FIG. 5 is a graph showing the relation between the number of cycles of the dummy film deposition process, and the repeatability of the thickness and the composition in the PZT film formed by the film deposition process subsequent to the dummy film deposition process to evaluate film deposition repeatability of the film deposition process for forming the PZT film more specifically. As obvious from the graph shown in FIG. 5, values of the film deposition repeatability for Pb and the thickness were not greater than 0.6% and a value of the film deposition repeatability for Zr was on the order of 1.0% after three cycles of the dummy film deposition process. Thus the values shown in FIG. 5 proved that the repeatability of the composition and the thickness of the PZT film can be improved by at least three cycles of the dummy film deposition process.

Definite relation between the number of cycles of the dummy film deposition process and film deposition repeatability for Ti was not found. Thus it is inferred that the film deposition repeatability for Ti is affected by a condition other than the composition of the atmosphere in the processing vessel, such as the temperature of the atmosphere in the processing vessel. The repeatability can be improved by using a dummy wafer provided with a base electrode metal film equivalent to that of a wafer, such as a noble metal electrode film, because the difference in the surface temperature of the shower head between a state where a bear Si wafer is placed on the stage and a state where a wafer provided with a base electrode metal film is placed on the stage is between 5° C. and 10° C. when the heating lamps are controlled so as to maintain the stage at a fixed temperature. A wafer provided with a base electrode metal film reflects some heat rays from the heating lamps and hence the surface temperature of the shower head in a state where a wafer provided with a base electrode metal film is placed on the stage is lower than that of the shower head in a state where a bare Si wafer is placed on the stage. Thus the variation of the surface temperature of the shower head can be suppressed by using a dummy wafer provided with a base electrode metal film and, consequently, the effect of Ti on the film deposition repeatability can be reduced.

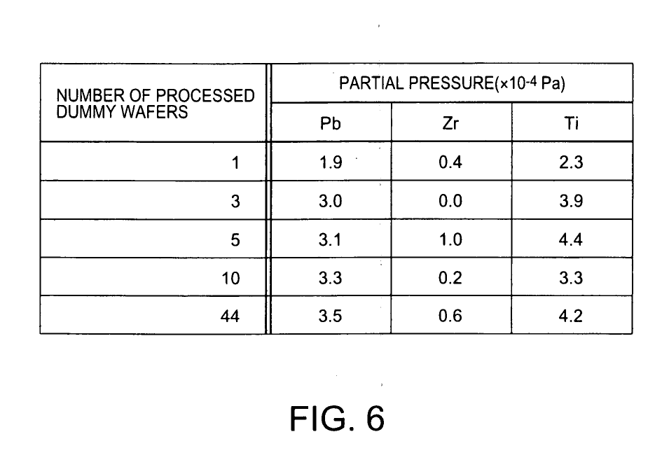

FIG. 6 is a table of partial pressures of the elements of the atmosphere in the processing vessel calculated by using measured partial pressures of the elements immediately after the completion of the dummy film deposition process for the numbers of dummy wafers processed by the dummy film deposition process. As shown in FIG. 6, the partial pressure of Pb in the atmosphere in the processing vessel immediately after three dummy wafers have been processed is 3.0×10⁻⁴ Pa, and the partial pressure of Pb saturates and does not change significantly even if the number of dummy wafers is increased beyond three. Thus, as mentioned above in the description of the first embodiment, the Pb concentration of the PZT film saturates and the partial pressure of Pb in the atmosphere in the processing vessel reaches a saturation partial pressure on the order of 3.0×10⁻⁴ Pa after at least three cycles of the dummy film deposition process. Process conditions are a Pb-base material supply rate of 0.8736 sccm, a Zr-base material supply rate of 0.6048 sccm, a Ti-base material supply rate of 1.8816 sccm and a process pressure of 133.3 Pa.

The condition for ending the dummy film deposition process and starting the film deposition film may be “the partial pressure of Pb in the processing vessel is 3.0×10⁻⁴ Pa” instead of “the repetition of the dummy film deposition process three times”.

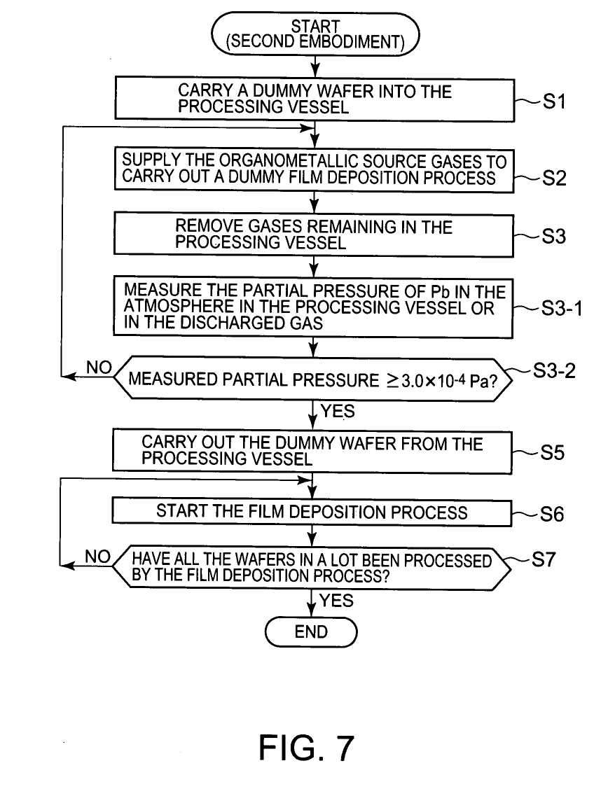

FIG. 7 is a flow chart of a film deposition method in a second embodiment according to the present invention. Steps S1 to S3 of the film deposition method in the second embodiment are exactly the same as steps S1 to S3 of the film deposition method in the first embodiment, respectively.

When a dummy film deposition process is started after the duration of an idling mode, a dummy wafer is carried into the processing vessel 4 and is placed on the stage 8 in step S1. After the dummy wafer has been heated at a predetermined temperature, the dummy film deposition process is carried out for a predetermined time in step S2 to deposit a PZT film on a surface of the dummy wafer. Process conditions including conditions for supplying the Pb-base, the Zr-base and the Ti-base material, namely, organometallic gases, and the oxidation gas into the processing vessel 4 in the dummy film deposition process are the same as those in the film deposition process for depositing a film on a wafer W.

After the dummy film deposition process has been continued for the predetermined time, the supply of the source gases and the oxidation gas is stopped and the gases remaining in the processing vessel 4 are removed in step S3 to complete the first cycle of the dummy film deposition process.

Then, step S3-1 characteristic of the second embodiment is executed. In step S3-1, the partial pressure of Pb in the atmosphere in the processing vessel 4 or in the exhaust gas is measured. The response to a query made in step S3-2 is negative if the measured partial pressure of Pb is below 3.0×10⁻⁴ Pa. Steps S2 and S3 are repeated until the partial pressure of Pb become not lower than 3.0×10⁻⁴ Pa. The dummy wafer may be changed every time one cycle of the dummy film deposition process is completed or the dummy wafer may be used by repeatedly for several cycles of the dummy film deposition process.

When the partial pressure of Pb increases to 3.0×10⁻⁴ Pa or above, i.e., if the response to a query made in step S3-2 is affirmative, steps like those of the first embodiment are executed. The dummy wafer is carried out from the processing vessel 4 in step S5. Subsequently, a wafer W is carried into the processing vessel 4 and is subjected to the film deposition process in step S6. The film deposition process is performed continuously for, for example, a lot of twenty-five wafers W while the response to a query made in step S7 is negative. The response to a query made in step S7 is affirmative after all the wafers W in a lot have been processed and the film deposition process is ended. Then, the film deposition system is kept in the idling mode.

The condition of the inside surfaces of the processing vessel 4 and the atmosphere in the processing vessel 4 can be stabilized by carrying out the dummy film deposition process until the partial pressure of Pb in the atmosphere in the processing vessel (or in the exhaust gas) increase to 3.0×10⁻⁴ Pa or above after the film deposition system has been kept in the idling mode before starting the film deposition process. Consequently, the repeatability of the composition and the thickness of the PZT film deposited on the surface of the wafer W can be improved. The concentration of Pb among the concentrations of the metals has a significant influence on the electric characteristic of the semiconductor device. The repeatability of the Pb concentration can be greatly improved.

Stabilization of the Pb-atmosphere in the processing vessel is an important purpose of the dummy film deposition process. Therefore, the organometallic gases for the dummy film deposition process must contain at least the Pb-base material, and the dummy film deposition process does not necessarily need the Zr-base material and the Ti-base material. From the point of view of stabilizing the atmosphere in the processing vessel, any dummy wafer does not necessarily need to be placed in the processing vessel.

### RELATED ART

Technical matters relating with the present invention will be described.

When the film deposition system is changed from the idling mode to the film deposition mode (or a dummy film deposition mode), only the solvent, such as butyl acetate, is supplied for a predetermined time to the atomizer 46 to stabilize the spraying operation of the spray nozzle 46A of the atomizer 46 before supplying the source gases. When the film deposition system is changed from the film deposition mode to the idling mode, only the solvent is supplied to the spray nozzle 46A for a predetermined time after stopping supplying the source gases to prevent the spray nozzle 46A from being clogged.

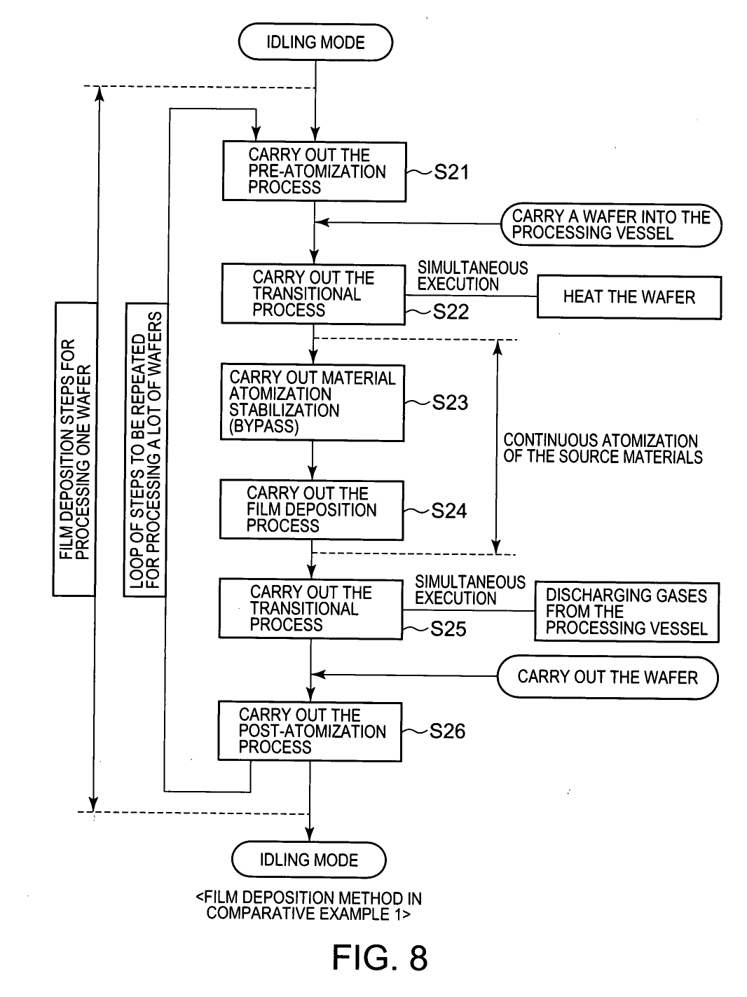

A film deposition process in Comparative example 1 will be described with reference to FIG. 8.

Referring to FIG. 8, when an idling mode is changed for a film deposition mode to carry out a film deposition process, a pre-atomization process is executed in step S21 to supply the solvent and the carrier gas to the atomizer 46 (FIG. 1) without supplying the Pb-base, the Zr-base and the Ti-base material, the solvent and the carrier gas are sprayed through the spray nozzle 46A, and then the sprayed solvent is atomized upon the contact with the inner surface of the atomizer 46. The solvent gas thus produced is not supplied into the processing vessel 4 and is discharged through the bypass line 52 into the exhaust line 22. Thus the operation of the atomizer 46 is stabilized. The pre-atomization process is continued for a time between about 2 and about 5 min. Then a transitional process is executed in step S22 to carry wafer W into the processing vessel 4 to supply and atomize the solvent without supplying the materials. Thus the stable operation of the atomizer 46 is maintained and the wafer W heated and is stabilized at a predetermined temperature. The transitional process is continued for a time between about 0.5 and abut 5 min.

Then, a material atomization stabilizing step S23 is executed to supply the materials and to produce the source gases by the atomizer 46. The source gases are not yet supplied into the processing vessel and is discharge through the bypass line 52 until the atomizing operation for atomizing the materials is stabilized. The material atomization stabilizing step S23 is continued for a time between abut 0.5 and abut 3 min.

After the material atomizing operation has been stabilized, the first shutoff valve 50B and the second shutoff valve 52B are operated so as to supply the source gases into the processing vessel 4 to carryout the film deposition process in step S24. After the completion of the film deposition process, the supply of the materials is stopped, and then a transitional process similar to the transitional process executed in step S22 is executed in step S25. During the transitional process in step S25, gases are discharged from the processing vessel 4. A post-atomization process is executed in step S26 after the wafer has been carried away from the processing vessel 4. The post-atomization process, similarly to the pre-atomization process executed in step S21, supplies only the solvent to the atomizer 46. Steps S21 to S26 are repeated continuously until the completion of processing all the twenty-five wafers in a lot. The materials are atomized continuously during operations in steps S23 and S24.

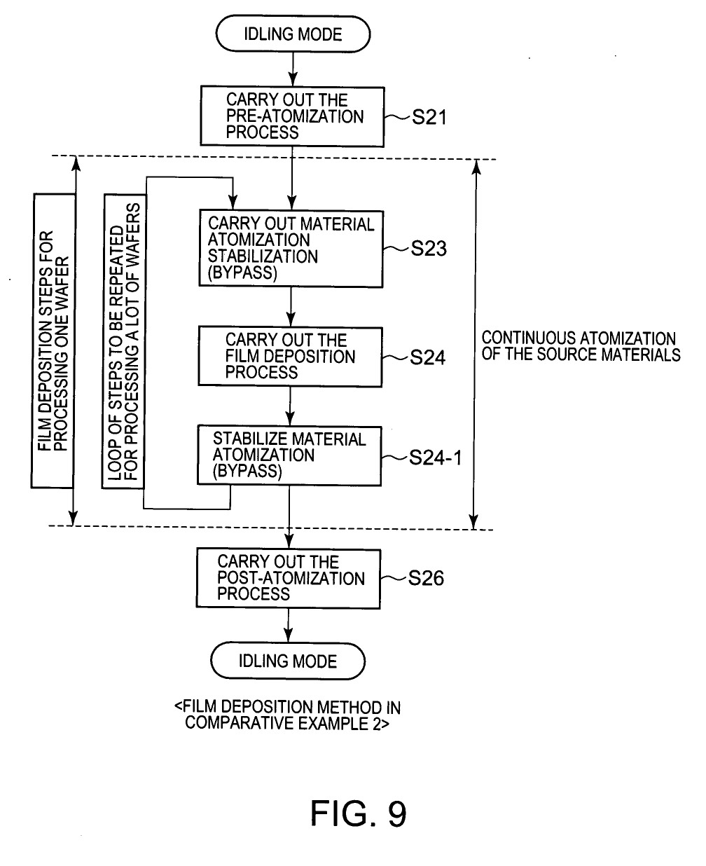

A film deposition process in Comparative example 2 will be described with reference to FIG. 9. This film deposition process in Comparative example 2 does not have a step for a transitional process. Referring to FIG. 9, an atomization stabilizing process is executed in step S23 directly subsequently to a pre-atomization process in step S21, and then the film deposition process is executed in step S24. Then, an atomization stabilizing process similar to that executed in step S23 is executed in step S24-1.

Steps S23, S24 and S24-1 are repeated and the materials are atomized continuously until the completion of processing, for example, all the twenty-five wafers in a lot. After the completion of processing all the twenty-five wafers in a lot, a post-atomization process is executed in step S26, and then the film deposition system is set again in the idling mode.

The film deposition method in Comparative example 1 shown in FIG. 8 executes the pre-atomization process in step S21 and the post-atomization process in step S26 in every cycle of the film deposition process for processing one wafer. Such a mode of processing wafers takes a long time for processing one wafer and the throughput of the film deposition system is inevitably low.

The film deposition method in Comparative example 2 shown in FIG. 9 executes the pre-atomization process only once for the first one of the wafers in a lot and executes the post-atomization process only once for the last one of the wafers in the lot. Although this film deposition method increases the through put, the consumption of the materials and the film deposition cost increase because the materials are atomized continuously throughout a period in which all the wafers in the lot are processed.

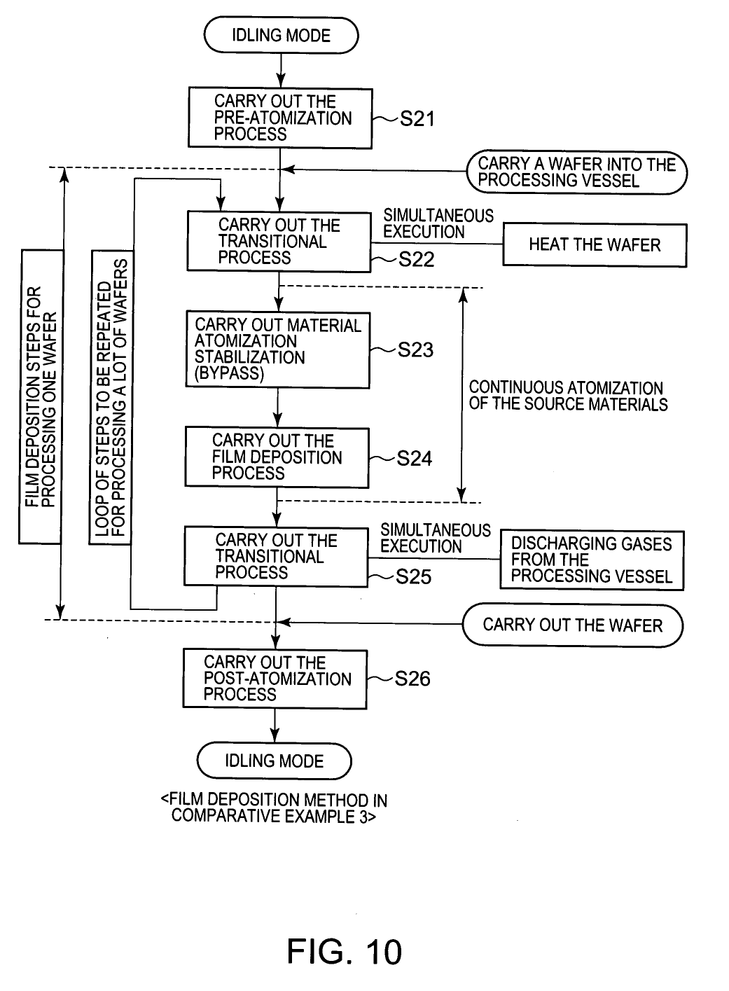

FIG. 10 shows a film deposition method developed by improving the steps of the film deposition process to solve the foregoing problems. The number of steps of the film deposition process illustrated by a flow chart shown in FIG. 10 is equal to that of steps of the film deposition process shown in FIG. 8. However, a loop of steps to be repeated to process a plurality of wafers in a lot in the film deposition method shown in FIG. 10 is different from that to be repeated to process a plurality wafers in a lot in the film deposition method shown in FIG. 8.

Referring to FIG. 10, a pre-atomization process is executed in step S21 after the termination of the idling mode, and a transitional process is executed in step S22 after a wafer has been placed in the processing vessel 4. The wafer is heated during the transitional process in step S22. An atomization stabilizing process is executed in step S23 after the completion of the transitional process in step S22. A film deposition process is executed in step S24 after the atomization of the materials has been stabilized. When the wafer is heated also in the atomization stabilizing process in step S23, the duration of the transitional process in step S22 may be reduced accordingly. A transitional process is executed in step S25 after the completion of the film deposition process in step S24 and, at the same time, gases contained in the processing vessel 4 are discharged and the wafer is carried away from the processing vessel 4. Steps S22 to S25 are repeated continuously until the completion of processing all the wafers in a lot. After all the wafers have been processed, a post-atomization process is executed in step S26 and the film deposition system is set in an idling mode.

In this improved film deposition method, the pre-atomization process is executed in step S21 only for the first wafer among those in a lot, and the post-atomization process is executed in step S26 only for the last wafer among those in the lot. Consequently, a time needed by the improved film deposition method is shorter than that needed by the film deposition method in Comparative example 1 for processing one wafer. Thus the improved film deposition method improves the throughput.

Only the inexpensive solvent is atomized instead of the expensive materials in the transitional process in step S22 before processing every wafer among the lot, and the transitional process is executed in step S25 after processing every wafer among the lot. Consequently, the consumption of the expensive materials can be suppressed and the film deposition cost can be reduced.

The throughput of the film deposition system carrying out the improved film deposition method was 1.6 times that of the film deposition system carrying out the film deposition method in Comparative example 1. The material cost of the improved film deposition method was about 80% of that of the film deposition method in Comparative example 2.

One of some of Zr-base materials, such as Zr(t-OC₄H₉)₄, Zr(t-OC₃H₇)₂(DPM)₂, Zr(DPM)₄, Zr(i-OC₃H₇)₄, Zr(C₅H₇O₂)₄ and Zr(C₅HF₆O₂)₄, may be used. A Ti-base material may be Ti(i-OC₃H₇)₄ or Ti(i-OC₃H₇)₂(DPM)₂.

The present invention is effective also in forming an oxide film containing Pb by using organic metal materials. Oxide films containing Pb are, for example, PbO films, PTO films, PZO films or PZT films containing Ca, La or Nb.

The present invention is applicable to depositing films, other than the PZT films, namely, oxide films of organometallic compounds, including ferroelectric films, such as BST films, SBT films and BLT films, high-temperature superconducting films of RE-Ba-Cu-O (RE indicates a rare earth element), Bi-Sr-Ca-Cu-O and TI-Ba-Ca-Cu-O systems, gate insulating films of Al₂O₃, HfO₂ and ZrO₂, oxide electrode films of RuO₂, IrO₂ and SrRuO systems. In the films mentioned above, BST, SBT and BLT are an oxide containing Ba, Sr and Ti, an oxide containing Sr, Bi and Ta, and an oxide containing Bi, La and Ti, respectively.

The workpiece is not limited to the semiconductor wafer and may be a LCD substrate, a glass substrate or the like.

1. A film deposition method of depositing a multielement metal oxide film on a surface of a workpiece by a film depositing process including supplying organometallic source gases generated by atomizing a plurality of organometallic compounds into a processing vessel capable of being evacuated;
wherein a dummy film deposition process corresponding to at least three cycles of the film deposition process is carried out by placing a dummy workpiece in the processing vessel and supplying the organometallic source gases into the processing vessel immediately before starting the film deposition process for depositing a multielement metal oxide film on the workpiece.

2. The film deposition method according to claim 1, wherein the plurality of organometallic compounds include a Pb-base organometallic compound.

3. A film deposition system for depositing a multielement metal oxide film on a surface of a workpiece, said film deposition system comprising:
a processing vessel capable of being evacuated;
a stage for supporting a workpiece thereon;
a heating means for heating the workpiece supported on the stage; and
a gas supply means for supplying a plurality of organometallic gases into the processing vessel;
wherein the partial pressure of a gas containing a predetermined metal and contained in an atmosphere in the processing vessel or in an exhaust gas discharged from the processing vessel is measured by a partial pressure measuring device, and
a control unit carries out control operations, immediately before starting a film deposition process for processing the workpiece, to carry out a dummy film deposition process including supplying the organometallic gases into the processing vessel holding a dummy workpiece, repeating the dummy film deposition process until the partial pressure of the gas containing the predetermined metal measured by the partial pressure measuring device immediately after the completion of the dummy film deposition process is not lower than a predetermined pressure level, and starting the film deposition process for processing the workpiece after the measured partial pressure has exceeded the predetermined pressure level.

4. The film deposition system according to claim 3, wherein the plurality of organometallic compounds include a Pb-base organometallic compound.

5. The film deposition system according to claim 4, wherein the predetermined pressure level is 3.0×10⁻⁴ Pa.
